(19) United States
(12) Patent Application Publication
(10) Pub. No.: US 2017/0110081 A1
(43) Pub. Date: Apr. 20, 2017

(54) DISPLAY PANEL AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventors: SHUAI HAN, Beijing (CN); LINGYUN SHI, Beijing (CN); HAO ZHANG, Beijing (CN); QUANHUA HE, Beijing (CN); BO GAO, Beijing (CN); JIALONG LI, Beijing (CN); DI WANG, Beijing (CN); WEI WANG, Beijing (CN)

(73) Assignees: BOE TECHNOLOGY GROUP CO., LTD., Beijing (CN); BEIJING BOE OPTOELECTRONICS TECHNOLOGY CO., LTD., Beijing (CN)

(21) Appl. No.: 15/115,040

(22) PCT Filed: Jan. 8, 2016
(86) PCT No.: PCT/CN2016/070459

§ 371 Date: Jul. 28, 2016

(30) Foreign Application Priority Data
Jul. 20, 2015 (CN) 201510427776.6

(51) Int. Cl. G09G 3/36

(52) U.S. Cl. CPC G09G 3/3696; G09G 3/3666; G09G 3/3677; G09G 2300/0426; G09G 2310/0286; G09G 2310/0291; G11C 19/287

(57) ABSTRACT

A display panel and a display device are disclosed. The display panel includes an array substrate (21) and a driving IC (11). The array substrate (21) includes a shift register (211). The shift register (211) includes a plurality of shift register units (2111) which are connected in multi stages. The array substrate (21) further includes a charge pump (22) which is connected with each of the shift register units (2111). An input terminal of the charge pump (22) is connected with the driving IC (11). An output terminal of the charge pump (22) is connected with each of the shift register units (2111). According to the disclosure, a charge pump is disposed on the array substrate, so as to lower a cost of the display panel.

### TECHNICAL FIELD

Embodiment of the disclosure relate to a display panel and a display device.

### BACKGROUND

With kinds of liquid crystal panels increasing, requirements on the liquid crystal panels is becoming higher and higher, for example, higher resolution of the liquid crystal panels, lower cost of the liquid crystal panels and an extra narrow bazel for the liquid crystal panels.

A conventional liquid crystal display panel comprises a thin film transistor array substrate, a driving integrated circuit (driving IC) and a flexible print circuit board (FPCB). The flexible print circuit board comprises a charge pump, and the array substrate comprises a shift register. FIG. 1 is a circuit diagram of the conventional liquid crystal display panel. As shown in FIG. 1, the driving IC 11 is connected with a charge pump of the flexible print circuit board 12, and the charge pump 120 is connected with a shift register 130 of the array substrate 13. The array substrate is disposed over the driving IC, and the flexible print circuit board is disposed below the driving IC. When the driving IC generates a voltage signal, the voltage signal is sent to the charge pump of the flexible print circuit board, then the voltage signal is amplified by the charge pump, and the amplified voltage signal is sent to the shift register of the array substrate.

The charge pump is also referred to as a switch capacitive voltage converter, which is a converter (DC-DC) to store energy by using a so-called “flying” or “pumping” capacitor. The charge pump enables an input voltage to be dropped or boosted. A field effect transistor (FET) switch array inside the charge pump stores energy in some manner and then releases the energy in a controlled manner, so that the input voltage is boosted or dropped in a factor (for example, 0.5, 2 or 3), to obtain a desired output voltage. The charge pump of the conventional liquid crystal display device is disposed on the flexible print circuit board, to amplify a source positive voltage VSP and a source negative voltage VSN provided by the driving IC, so as to generate a high gate voltage VGH and a low gate voltage VGL. It is required to provide a charge pump on the flexible print circuit board, to improve a voltage control switching, resulting a high cost of the liquid crystal display device.

In summary, in the conventional display panel, the charge pumper is provided on the flexible print circuit board, which increases the cost of the display panel.

### SUMMARY

Embodiments of the disclosure provide a display panel and a display device, wherein a charge pump is disposed on an array substrate, so as to reduce a cost of the display panel and increase product competitiveness of the display panel.

An embodiment of the disclosure provides a display panel. The display panel comprises an array substrate and a driving IC, wherein the array substrate comprises a shift register, and the shift register comprises a plurality of shift register units which are connected in multi stages; the array substrate further comprises a charge pump which is connected with each of the shift register units, an input of the charge pump is connected with the driving IC, and an output of the charge pump is connected with each of the shift register units.

In the display panel according to an embodiment of the disclosure, the charge pump is disposed on the array substrate, to save the charge pump on the flexible circuit board, so as to lower a cost of the display panel and increase product competitiveness of the display panel.

In an example, the charge pump is configured to amplify a voltage signal output from the driving IC, and output the amplified voltage signal to each of the shift register units.

In an example, each stage of the shift register units is connected with a group of gate lines, every two adjacent rows of the gate lines are a group of gate lines, and the gate lines of different groups do not share same gate lines.

In an example, the array substrate comprises a first shift register disposed at a left bazel of the display panel, a second shift register disposed at a right bazel of the display panel, a first charge pump connected with the first shift register and a second charge pump connected with the second shift register.

Each of the left and right bazels is provided with a charge pump, so that when the charge pump disposed at the left bazel can not be operated normally, the display panel can provide voltage signals to the shift register units through the charge pump disposed at the right bazel to drive gate lines such that the display panel can be operated normally; or when the charge pump disposed at the right bazel can not be operated normally, the display panel can provide voltage signals to the shift register units through the charge pump disposed at the left bazel to drive the gate lines, such that the display panel can be operated normally.

In an example, each stage of the shift register units of the first shift register and a same stage of the shift register unit of the second shift register are connected with a same group of the gate lines, every two adjacent rows of the gate lines are a group of gate lines, and the gate lines of different groups do not share same gate lines.

Each stage of the shift register units of the shift register disposed at the left bazel and a same stage of the shift register unit of the shift register disposed at the right bazel are connected with a same group of the gate lines, to achieve a narrow bazel design.

In an example, each stage of the shift register units of the first shift register is connected with odd-numbered rows of the gate lines, and each stage of the shift register units of the second shift register is connected with even-numbered rows of the gate lines; or each stage of the shift register units of the first shift register is connected with even-numbered rows of the gate lines, and each stage of the shift register units of the second shift register is connected with odd-numbered rows of the gate lines.

Each stage of the shift register units of the shift register disposed at the left bazel is connected with odd-numbered rows of the gate lines, and each stage of the shift register units of the shift register disposed at the right bazel is connected with even-numbered rows of the gate lines, to achieve the narrow bazel design.

In an example, the shift register comprises n stages of shift register units, an input signal of n-th stage of the shift register unit (1<n<N) is provided by an output terminal of (n−1)-th stage of the shift register unit, and a reset signal of n-th stage of the shift register unit is provided by an output terminal of (n+1)-th stage of the shift register unit, wherein n is a positive integer larger than 1.

In an example, each stage of the shift register units comprises a first input terminal configured to be input a high level signal and a second input terminal configured to be input a low level signal, and the first and second input terminals are connected with a first output terminal configured to output the high level signal and a second output terminal configured to output the low level signal of the charge pump, respectively.

In an example, each stage of the shift register units is an identical shift register unit.

Embodiments of the disclosure provide a display device, comprising the display panel according to the embodiments of the disclosure.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus the skilled in this art can obtain other drawings from these drawings without any inventive work.

FIG. 1 is an illustrative structural diagram of a display panel in prior art;

FIG. 2 is an illustrative structural diagram of a display panel according to an embodiment of the disclosure;

FIG. 3 is an illustrative structural diagram of a shift register according to an embodiment of the disclosure;

FIG. 4 is an illustrative structural diagram of another display panel according to an embodiment of the disclosure;

FIG. 5 is an illustrative structural diagram of a third display panel according to an embodiment of the disclosure; and

FIG. 6 is an illustrative structural diagram of a fourth display panel according to an embodiment of the disclosure.

### DETAILED DESCRIPTION

In order to make objects, technical details and advantages of the embodiments of the invention apparent, the technical solutions of the embodiments will be described in a clearly and fully understandable way in connection with the drawings related to the embodiments of the invention. Apparently, the described embodiments are just a part but not all of the embodiments of the invention. Based on the described embodiments herein, those skilled in the art can obtain other embodiment(s), without any inventive work, which should be within the scope of the invention.

Unless defined otherwise, all the technical and scientific terms used herein have meanings as commonly understood by one of ordinary skill in the art to which the present disclosure belongs. The terms, such as “first,” “second” or the like, which are used in the description and the claims of the present disclosure, are not intended to indicate any sequence, amount or importance, but for distinguishing various components. Also, the terms, such as “a/an,” “one,” “the/said” or the like, are not intended to limit the amount, but for indicating the existence of at lease one element. The terms, such as “connection/connecting/connected,” or the like, are not intended to define a physical connection or mechanical connection, but may include an electrical connection/coupling, direct or indirect. The terms, such as “on,” “under,” “left,” “right,” or the like, are only used to indicate relative position relationship, and when the position of the object which is described is changed, the relative position relationship may be changed accordingly. A thickness and shape of thin films of the drawings does not reflect a real proportion, and it only illustrates the disclosure.

Embodiments of the disclosure provide a display panel and a display device, wherein a charge pump is disposed on an array substrate, so as to reduce a cost of the display panel and increase product competitiveness of the display panel.

Technical solutions according to the embodiments of the disclosure will be particularly described below in connection with the accompanying drawings.

### Embodiment One

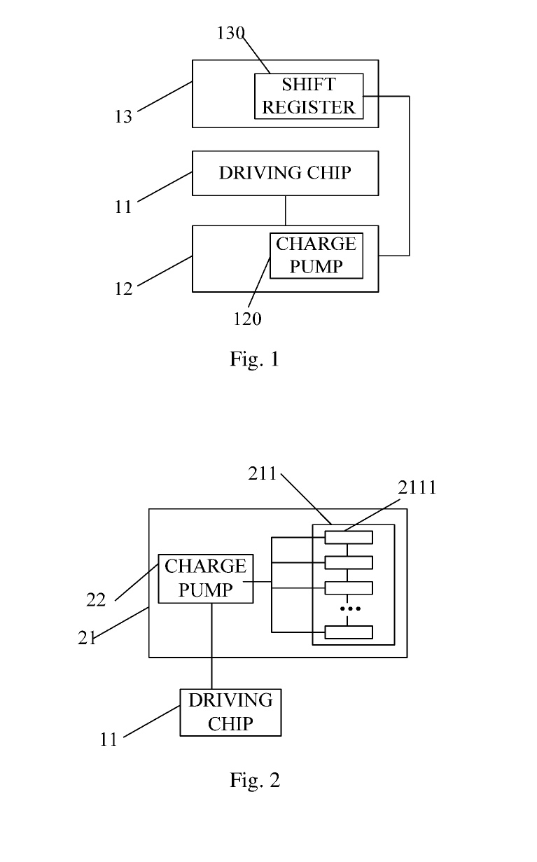

Referring to FIG. 2, an embodiment of the disclosure provides a display panel. The display panel comprises an array substrate 21 and a driving IC 11. The array substrate 21 comprises a shift register 211. The shift register 211 comprises a plurality of shift register units 2111 which are connected in multiple stages. All of the shift register units 2111 can be identical. The array substrate 211 further comprises a charge pump 22 which is connected with each of the shift register units. An input terminal of the charge pump 22 is connected with the driving IC 11, and an output terminal of the charge pump 22 is connected with each of shift register units 2111.

It should be noted that, in the display panel, the array substrate is disposed on the driving IC. Compared to FIG. 1, the charge pump of the embodiment of the disclosure is provided on the array substrate, so that a connection distance between the charge pump and the shift register units is reduced, to save electronic devices of the charge pump on the flexible circuit board, which in turn lowers a cost of the display panel and increases product competitiveness of the display panel.

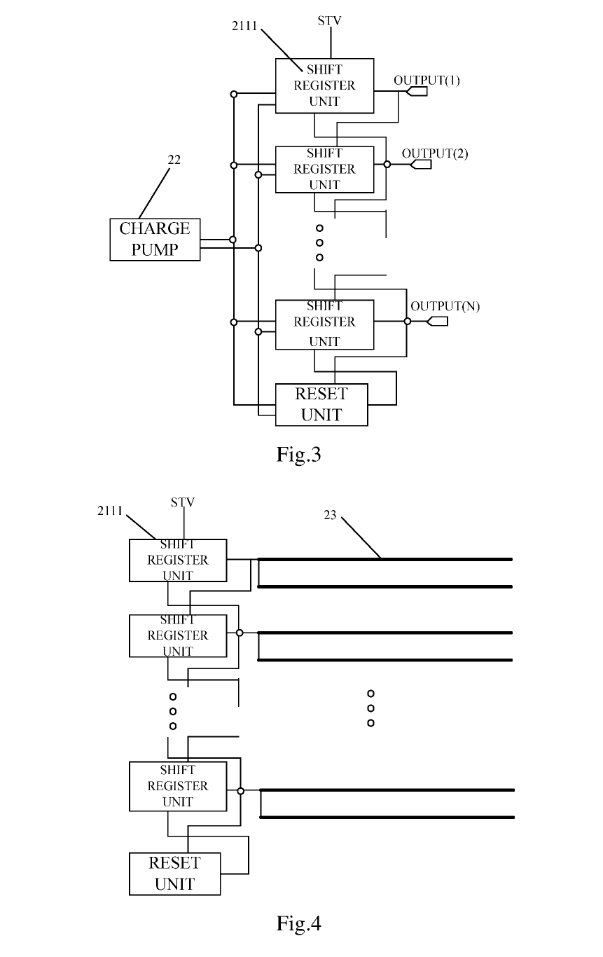

A manner of connection in multiple stages of the shift register units will be briefly introduced to make a principle of the shift register more clear. For example, referring to FIG. 3, the entire shift register totally has N stages of shift register units. A signal to an input terminal (INPUT) of a first stage of the shift register unit is supplied by a Start Vertical signal (STV), a reset (RESET) signal of the first stage of the shift register unit is supplied by an output (OUTPUT) signal of a second stage of the shift register unit, an INPUT signal of a N-th stage of the shift register unit is supplied by an output signal of a (N−1)-th stage of the shift register unit, and a RESET signal of the N-th stage of the shift register unit is supplied by a RESET unit. For example, an INPUT signal of the n-th stage (wherein n is greater than 1 and less than N) of the shift register unit is supplied by an OUTPUT signal of the (n−1)-th stage of the shift register unit, and a RESET signal of the n-th stage of the shift register unit is supplied by an OUTPUT signal of the (n+1)-th stage of the shift register unit.

Each stage of the shift register unit is further provided with two input terminals, configured to be input a high level signal VGH and a low level signal VGL respectively, and the two input terminals are connected with a first output terminal configured to be output the high level signal VGH and a second output terminal configured to be output the low level signal VGL of the charge pump 22, respectively.

For example, the charge pump 22 is configured to amplify a voltage signal output from the driving IC 11, and output the amplified voltage signal to each of the shift register units 2111.

The output voltages of the driving IC 11 are VSP and VSN, the output voltages charges a capacitor which control transmittance of pixel units, wherein the VSP is a positive voltage and the VSN is a negative voltage. The charge pump 22 is configured to amplify the voltage signals VSP and VSN, to obtain a high level signal VGH and a low level signal VGL which are used to input the shift register 211. The low level signal VGL and the high level signal VGH are supplied to the shift register 211 so as to output scan signals for driving gate electrodes.

In this embodiment, the charge pump 22 is disposed on the array substrate 21, so that the charge pump 22 amplifies the voltages VSP and VSN to generate the high level signal VGH and the low level signal VGL and output them to each of the shift register units 2111 when the driving IC 11 outputs voltage signals VSP and VSN to the charge pump. Because all the charge pumps 22 and each of the shift register units 2111 are disposed on the array substrate 21, a distance between the charge pump and each of the shift register units is reduced, so as to reduce a period for transmitting signals.

For example, referring to FIG. 4, each stage of the shift register units 2111 of the array substrate is connected with a group of gate lines 23. Every two adjacent rows of gate lines 23 form a group of gate lines, and a group of gate lines which are connected with a stage of the shift register units 2111 and a group of gate lines which are connected with another stage of the shift register units 2111 does not share a common gate line.

It should be noted that, an output terminal of each stage of the shift register units can be connected with two rows of gate lines simultaneously, so that when the shift register unit outputs a high level, the two rows of gate lines connected with the shift register unit are scanned simultaneously, to achieve a narrow bazel design when the display panel is a super high definition or a high definition display panel.

For example, when both right and left bazels of the array substrate are provided with shift registers, the array substrate comprises a first charge pump which is connected with a shift register disposed at the left bazel and a second charge pump which is connected with a shift register disposed at the right bazel.

It should be noted that, the first charge pump and the second charge pump have a same configuration. The first charge pump and the second charge pump can be a same charge pump or may be two identical charge pumps. This is not limited in the embodiment of the disclosure.

Both the left and right bazels are provided with a charge pump, so that when the charge pump disposed at the left bazel can not be operated normally, the display panel can provide voltage signals to the shift register units through the charge pump disposed at the right bazel to drive gate lines such that the display panel can work normally; or when the charge pump disposed at the right bazel can not be operated normally, the display panel can provide voltage signals to the shift register units through the charge pump disposed at the left bazel to drive the gate lines, such that the display panel can be operated normally.

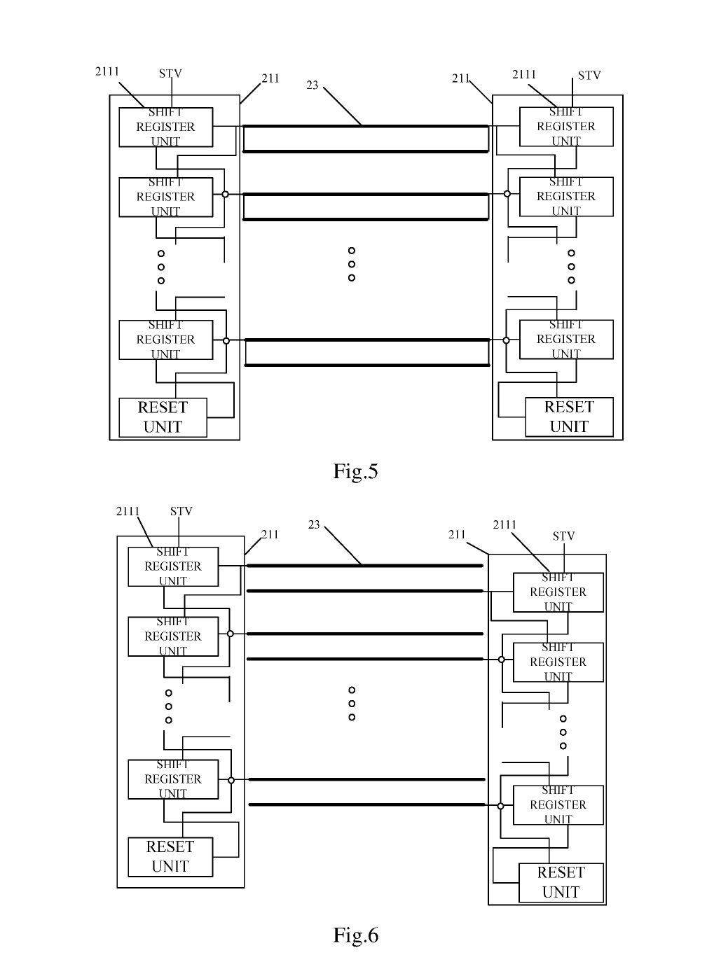

In an example, referring to FIG. 5, when both the left bazel and the right bazel have shift registers 211, each stage of the shift register units 2111 of the shift register 211 disposed at the left bazel and a same stage of the shift register units 2111 of the shift register 211 disposed at the right bazel are connected with a same group of gate lines. Every two adjacent rows of gate lines 23 are a group of gate lines, and different groups of gate lines comprise different gate lines.

Each stage of the shift register units of the shift register disposed at the left bazel and a same stage of the shift register units of the shift register disposed at the right bazel are connected with a same group of the gate lines, to achieve a narrow bazel design. Particularly, in operation, the shift register disposed at the left bazel or the shift register disposed at the right bazel can be operated alone, so that when the shift register disposed at the left bazel can not be operated normally, the shift register disposed at the right bazel can be operated to drive the gate lines and the two rows of the gate lines can be driven simultaneously, to make the display panel be operated normally and to achieve the narrow fame design; or when the shift register disposed at the right bazel can not be operated normally, the shift register disposed at the left bazel can be operated to drive the gate lines and the two rows of the gate lines can be driven simultaneously, to make the display panel to be operated normally and to achieve the narrow bazel design.

In another example, referring to FIG. 6, when both left bazel and right bazel are provided with a shift register 211, each stage of the shift register units 2111 of the shift register 211 disposed at the left bazel is connected with odd-numbered rows of the gate lines, and each stage of the shift register units 2111 of the shift register 211 disposed at the right bazel is connected with even-numbered rows of the gate lines (FIG. 5 only illustrates that each stage of the shift register units 2111 of the shift register 211 disposed at the left bazel is connected with odd-numbered rows of the gate lines).

Alternatively, each stage of the shift register units 2111 of the shift register 211 disposed at the left bazel is connected with even-numbered rows of the gate lines, and each stage of the shift register units 2111 of the shift register 211 disposed the right bazel is connected with odd-numbered rows of the gate lines.

In operation, when each stage of the shift register units 2111 of the shift register 211 disposed at the left bazel is connected with odd-numbered rows of the gate lines, and each stage of the shift register units 2111 of the shift register 211 disposed at the right bazel is connected with even-numbered rows of the gate lines, the shift register units disposed in the left bazel and the right bazel scan alternately, that is, a first stage of the shift register units disposed at the left bazel scans a first row of the gate line, and then a first stage of the shift register units disposed at the right bazel scans a second row of the gate line, and a second stage of the shift register units disposed at the left bazel scans a third row of the gate line, and then a second stage of the shift register units disposed at the right bazel scans a fourth row of the gate line, and so on, so as to scan all of the gate lines.

Each stage of the shift register units of the shift register disposed at the left bazel is connected with odd-numbered rows of the gate lines, and each stage of the shift register units of the shift register disposed at the right bazel is connected with even-numbered rows of the gate lines, to achieve a narrow bazel design.

Another embodiment of the disclosure provides a display device, comprising the display panel according to above embodiments of the disclosure.

In summary, a display panel according to embodiments of the disclosure comprises an array substrate and a driving IC, wherein the array substrate comprises a shift register, which comprises a plurality of same shift register units which are connected in multi stages. The array substrate further comprises a charge pump which is connected with each of the shift register units. An input terminal of the charge pump is connected with the driving IC, and an output terminal of the charge pump is connected with each of the shift register units. The charge pump is disposed on the array substrate, to save the charge pump on the flexible circuit board, so as to lower a cost of the display panel and increase product competitiveness of the display panel.

The above mentioned embodiments are only exemplary, and can not be construed as a limit to the disclosure. One of ordinary skill in the art can make various variations and modifications without departing from the spirit and the scope of the disclosure, and thus all of equivalent technical solutions fall into the scope of the disclosure and the scope of the disclosure are defined by the accompanying claims.

1. A display panel, comprising an array substrate and a driving IC, the array substrate comprising a shift register which comprises a plurality of shift register units which are connected in multi stages, wherein the array substrate further comprises a charge pump which is connected with each of the shift register units, an input terminal of the charge pump is connected with the driving IC, and an output terminal of the charge pump is connected with each of the shift register units.

2. The display panel of claim 1, wherein the charge pump is configured to amplify a voltage signal output from the driving IC and output the amplified voltage signal to each of the shift register units.

3. The display panel of claim 1, wherein each stage of the shift register units is connected with a group of gate lines, every two adjacent rows of the gate lines form a group of gate lines, and the gate lines of different groups do not share a common gate line.

4. The display panel of claim 1, wherein the array substrate comprises a first shift register disposed at a left bazel of the display panel, a second shift register disposed at a right bazel of the display panel, a first charge pump connected with the first shift register and a second charge pump connected with the second shift register.

5. The display panel of claim 4, wherein each stage of the shift register units of the first shift register and a same stage of the shift register units of the second shift register are connected with a same group of the gate lines, every two adjacent rows of the gate lines form a group of gate lines, and the gate lines of different groups do not share a common gate line.

6. The display panel of claim 4, wherein each stage of the shift register units of the first shift register is connected with odd-numbered rows of the gate lines, and each stage of the shift register units of the second shift register is connected with even-numbered rows of the gate lines; or
each stage of the shift register units of the first shift register is connected with even-numbered rows of the gate lines, and each stage of the shift register units of the second shift register is connected with odd-numbered rows of the gate lines.

7. The display panel of claim 1, wherein the shift register comprises N stages of shift register units, an input signal of n-th stage of the shift register units is supplied by an output of (n−1)-th stage of the shift register units, and a reset signal of n-th stage of the shift register units is supplied by an output of (n+1)-th stage of the shift register units, wherein 1<n<N, and N is a positive integer larger than 1.

8. The display panel of claim 1, wherein each stage of the shift register units comprises a first input terminal configured to be input a high level signal and a second input configured to be input a low level signal, and the first and second input terminals are connected with a first output terminal configured to output the high level signal and a second output terminal configured to output the low level signal of the charge pump, respectively.

9. The display panel of claim 1, wherein each stage of the shift register units is an identical shift register unit.

10. A display device comprising the display panel of claim 1.

11. The display panel of claim 2, wherein each stage of the shift register units is connected with a group of gate lines, every two adjacent rows of the gate lines form a group of gate lines, and the gate lines of different groups do not share a common gate line.

12. The display panel of claim 2, wherein the array substrate comprises a first shift register disposed at a left bazel of the display panel, a second shift register disposed at a right bazel of the display panel, a first charge pump connected with the first shift register and a second charge pump connected with the second shift register.

13. The display panel of claim 3, wherein the array substrate comprises a first shift register disposed at a left bazel of the display panel, a second shift register disposed at a right bazel of the display panel, a first charge pump connected with the first shift register and a second charge pump connected with the second shift register.

14. The display panel of claim 5, wherein each stage of the shift register units of the first shift register is connected with odd-numbered rows of the gate lines, and each stage of the shift register units of the second shift register is connected with even-numbered rows of the gate lines; or
each stage of the shift register units of the first shift register is connected with even-numbered rows of the gate lines, and each stage of the shift register units of the second shift register is connected with odd-numbered rows of the gate lines.

15. The display panel of claim 2, wherein the shift register comprises N stages of shift register units, an input signal of n-th stage of the shift register units is supplied by an output of (n−1)-th stage of the shift register units, and a reset signal of n-th stage of the shift register units is supplied by an output of (n+1)-th stage of the shift register units, wherein 1<n<N, and N is a positive integer larger than 1.

16. The display panel of claim 3, wherein the shift register comprises N stages of shift register units, an input signal of n-th stage of the shift register units is supplied by an output of (n−1)-th stage of the shift register units, and a reset signal of n-th stage of the shift register units is supplied by an output of (n+1)-th stage of the shift register units, wherein 1<n<N, and N is a positive integer larger than 1.

17. The display panel of claim 4, wherein the shift register comprises N stages of shift register units, an input signal of n-th stage of the shift register units is supplied by an output of (n−1)-th stage of the shift register units, and a reset signal of n-th stage of the shift register units is supplied by an output of (n+1)-th stage of the shift register units, wherein 1<n<N, and N is a positive integer larger than 1.

18. The display panel of claim 5, wherein the shift register comprises N stages of shift register units, an input signal of n-th stage of the shift register units is supplied by an output of (n−1)-th stage of the shift register units, and a reset signal of n-th stage of the shift register units is supplied by an output of (n+1)-th stage of the shift register units, wherein 1<n<N, and N is a positive integer larger than 1.

19. The display panel of claim 2, wherein each stage of the shift register units comprises a first input terminal configured to be input a high level signal and a second input configured to be input a low level signal, and the first and second input terminals are connected with a first output terminal configured to output the high level signal and a second output terminal configured to output the low level signal of the charge pump, respectively.

20. The display panel of claim 3, wherein each stage of the shift register units comprises a first input terminal configured to be input a high level signal and a second input configured to be input a low level signal, and the first and second input terminals are connected with a first output terminal configured to output the high level signal and a second output terminal configured to output the low level signal of the charge pump, respectively.
